(19) United States
(12) Patent Application Publication
(10) Pub. No.: US 2017/0194239 A1
(43) Pub. Date: Jul. 6, 2017

(54) A SEMICONDUCTOR PACKAGE HAVING AN ETCHED GROOVE FOR AN EMBEDDED DEVICE FORMED ON BOTTOM SURFACE OF A SUPPORT SUBSTRATE AND A METHOD FOR FABRICATING THE SAME

(71) Applicant: Amkor Technology, Inc., Tempe, AZ (US)

(72) Inventors: Ji Yeon Ryu, Seoul (KR); Byong Jin Kim, Bucheon-si (KR); Jae Beum Shim, Incheon (KR)

(21) Appl. No.: 15/149,436

(22) Filed: May 9, 2016

(30) Foreign Application Priority Data
Jan. 6, 2016 (KR) 10-2016-0001657

(51) Int. Cl. H01L 23/498; H01L 21/48; H01L 21/56; H01L 23/31

(52) U.S. Cl. CPC H01L 23/49838; H01L 23/49816; H01L 23/49822; H01L 23/3114; H01L 21/4853; H01L 21/4857; H01L 21/565; H01L 2021/60022

(57) ABSTRACT

A semiconductor device with etched grooves for embedded devices is disclosed and may, for example, include a substrate comprising a top surface and a bottom surface, a groove extending into the substrate from the bottom surface, and a redistribution structure in the substrate between the top surface and the bottom surface of the substrate. A semiconductor die may, for example, be coupled to the top surface of the substrate. An electronic device may, for example, be at least partially within the groove and electrically coupled to the redistribution structure. A conductive pad may, for example, be on the bottom surface of the substrate. A conductive bump may, for example, be on the conductive pad. The electronic device in the groove may, for example, extend beyond the bottom surface of the substrate a distance that is less than a height of the conductive bump from the bottom surface of the substrate. An encapsulant may, for example, encapsulate the semiconductor die and the top surface of the substrate. The electronic device may, for example, comprise a capacitor.

### CROSS REFERENCE TO RELATED APPLICATIONS

The present application makes reference to, claims priority to, and claims the benefit of Korean Patent Application No. 10-2016-0001657, filed on Jan. 6, 2016, the contents of which are hereby incorporated herein by reference, in their entirety.

### FIELD

Certain example embodiments of the disclosure relate to semiconductor device packaging. More specifically, certain example embodiments of the disclosure relate to a semiconductor device with etched grooves for embedded devices.

### BACKGROUND

While product packaging continues to trend toward miniaturization, it is desirable for semiconductor devices incorporated into such products to have increased functionality and/or reduced size. In addition, to reduce the size of a semiconductor device, the area and/or thickness of the semiconductor device may be reduced.

Further limitations and disadvantages of conventional and traditional approaches will become apparent to one of skill in the art, through comparison of such systems with the present disclosure as set forth in the remainder of the present application with reference to the drawings.

### BRIEF SUMMARY

Various aspects of this disclosure provide a semiconductor device with etched grooves for embedded devices, substantially as shown in and/or described in connection with at least one of the figures, as set forth more completely in the claims.

Various advantages, aspects and novel features of the present disclosure, as well as details of various illustrated example supporting embodiments, will be more fully understood from the following description and drawings.

### BRIEF DESCRIPTION OF SEVERAL VIEWS OF THE DRAWINGS

FIG. 1 is a cross-sectional view of a semiconductor device according to an embodiment of the present disclosure.

FIG. 2 is a flowchart illustrating a method of fabrication of a semiconductor device according to an embodiment of the present disclosure.

FIGS. 3 to 9 illustrate various steps of the method of fabrication of a semiconductor device shown in FIG. 2.

### DETAILED DESCRIPTION

Certain aspects of the disclosure may be found in a semiconductor device with etched grooves for embedded devices. Example aspects of the disclosure may comprise a substrate comprising a top surface and a bottom surface, a redistribution structure in the substrate between the top surface of the substrate and the bottom surface of the substrate, and an etched region, or groove, extending into the substrate from the bottom surface to the redistribution structure. A semiconductor die may, for example, be coupled to the top surface of the substrate and an electronic device may be at least partially within the etched region and electrically coupled to the redistribution structure. A conductive pad may, for example, be on the bottom surface of the substrate. A conductive bump may, for example, be on the conductive pad. The electronic device in the etched region may, for example, extend beyond the bottom surface of the substrate a distance that is less than a height of the conductive bump from the bottom surface of the substrate. An encapsulant may, for example, encapsulate the semiconductor die and the top surface of the substrate. The electronic device may, for example, comprise a capacitor. The redistribution structure may, for example, be electrically coupled to a second redistribution structure in the substrate. The semiconductor die may, for example, be electrically coupled to the second redistribution structure.

This disclosure provides example embodiments supporting the present disclosure. The scope of the present disclosure is not limited by these example embodiments. Numerous variations, whether explicitly provided for by the specification or implied by the specification, such as variations in structure, dimension, type of material and manufacturing process, may be implemented by one skilled in the art in view of this disclosure.

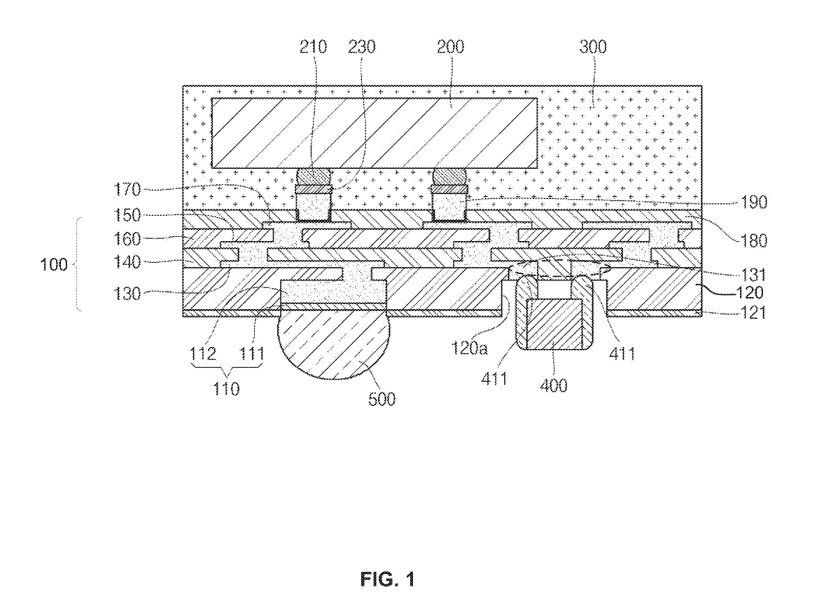

FIG. 1 is a cross-sectional view of a semiconductor device according to an embodiment of the present disclosure.

Referring to FIG. 1, the semiconductor device according to an embodiment of the present disclosure may include a substrate 100, a semiconductor die 200, an encapsulant 300, an electronic device 400, and a conductive bump 500.

The substrate 100 may comprise an interposer, for example, although the disclosure is not so limited, and may comprise any support structure with insulating and conductive regions. The substrate 100 may comprise various conductive layers formed on polyimide, for example. In another example scenario, the substrate 100 may comprise various conductive layers and dielectric layers stacked on a silicon wafer or glass. The substrate 100 may comprise a conductive pad 110 at a bottom surface of the substrate 100, a first dielectric layer 120 covering regions other than a bottom surface of the conductive pad 110, and a first redistribution structure 130 (e.g., a conductive layer, etc.) electrically connected to the conductive pad 110 and formed at a top surface of the first dielectric layer 120.

The substrate 100 may also comprise a second dielectric layer 140 covering a portion of the first redistribution structure 130, a second redistribution structure 150 (e.g., a conductive layer, etc.) formed along a top surface of the second dielectric layer 140, a third dielectric layer 160 surrounding a portion of the second redistribution structure 150, a third redistribution structure 170 (e.g., a conductive layer, etc.) formed at a top surface of the third dielectric layer 160, a fourth dielectric layer 180 covering a portion of a top surface of the third redistribution structure 170, and a conductive pattern 190 (e.g., traces, pads, lands, etc.) electrically connected to an exposed region of the third redistribution structure 170.

Here, the semiconductor device according to an embodiment of the present disclosure may be formed without the second redistribution structure 150 to the conductive pattern 190, or with additional dielectric layers and redistribution structures, depending on the required complexity. For example, the top surface of the first redistribution structure 130 or the second redistribution structure 150 may be exposed to function as a conductive pattern (e.g., as the conductive pattern 190).

The conductive pad 110 may be exposed through the bottom surface of the substrate 100 (e.g., through the bottom surface of the first dielectric layer 120, etc.). The example, conductive pad 110 includes a metal pad 112 and a bump pad 111 (e.g., comprising under bump metallization, etc.) positioned under the metal pad 112.

The bump pad 111 may be coupled to a surface of the metal pad 112. The bump pad 111 may have substantially the same width as the metal pad 112 and may be formed to increase adhesion between the metal pad 112 and the conductive bump 500. The bump pad 111 may comprise nickel gold (Ni/Au), for example, but the disclosure is not so limited. Since the adhesion between a copper pad and a solder bump may be weak, the bump pad 111 positioned between the metal pad 112 and the conductive bump 500 may increase the adhesion.

The metal pad 112 may comprise copper (Cu), for example, since copper exhibits excellent electrical conductivity that may be advantageous in signal transfer through the metal pad 112. However, the metal pad 112 may comprise any suitable conductive layer for receiving an electrical contact to the substrate 100.

The first dielectric layer 120 may be formed to surround the conductive pad 110. As described below, the first dielectric layer 120 may be formed on the surface of the substrate 100 having the conductive pad 110 formed thereon while surrounding the conductive pad 110. In this case, since the bump pad 111 formed on the metal pad 112 is in contact with the substrate 100, a bottom surface of the bump pad 111 may be exposed through openings in the first dielectric layer 120 in a subsequent step of removing portions of the substrate 100.

The first dielectric layer 120 (as with any or all dielectric layers discussed herein) may comprise one or more layers of any of a variety of dielectric materials, for example inorganic dielectric material (e.g., Si₃N₄, SiO₂, SiON, SiN, oxides, nitrides, combinations thereof, equivalents thereof, etc.) and/or organic dielectric material (e.g., a polymer, polyimide (PI), benzocyclobutene (BCB), polybenzoxazole (PBO), bismaleimide triazine (BT), a molding material, a phenolic resin, an epoxy, silicone, acrylate polymer, combinations thereof, equivalents thereof, etc.), but the scope of the present disclosure is not limited thereto

In addition, the first dielectric layer 120 may comprise an electronic device groove 120a (or cavity) formed in the first dielectric layer 120 to expose the first redistribution structure 130 for electrical contact thereto. The electronic device groove 120a may be formed to a predetermined depth of the first dielectric layer 120, thereby exposing an electronic device coupling structure 131 (or region) of the first redistribution structure 130. Note that in various example implementations, the groove 120a may extend through multiple dielectric layers (e.g., two dielectric layers, three dielectric layers, etc.) to expose a selected redistribution structure for electrical connection thereto.

The groove 120a (or cavity) may be formed in various shapes, depending on the shape of the electronic device to be placed within. For example, the groove 120a may comprise a long thin channel for linear structures, or a square or round opening for similarly shaped devices. Accordingly, the electronic device 400 may be coupled to the substrate 100 at a bottom portion of the substrate 100 and electrically connected to the electronic device coupling structure 131 (or region). Since the electronic device 400 may be positioned in the groove in the substrate 100 between the substrate and an external circuit board (not shown) coupled to the bottom portion of the substrate 110, it is possible to prevent or inhibit the overall thickness of the semiconductor device from increasing, even with relatively large devices placed within. In addition, since the thickness of the electronic device 400 is equal to or smaller than a sum of a depth of the electronic device groove 120a and a height of the conductive bump 500, the larger available height provides a greater degree of freedom in selecting the electronic device 400.

In addition, bottom regions of the first dielectric layer 120 may be covered by a dielectric layer 121. The dielectric layer 121 may comprise a silicon oxide layer, for example, that may be provided by preparing or utilizing a carrier substrate made of a silicon material, which is described below. In a subsequent step of removing the carrier substrate, the carrier substrate may be formed such that it remains only in a region of the first dielectric layer 120, except for the conductive pad 110 and the electronic device groove 120a. The dielectric layer 121 may electrically insulate (or further electrically insulate) the bottom surface of the substrate 100, thereby increasing the electrical reliability. Accordingly, in an example implementation in which an additional dielectric layer is desired, an additional process step to form such layer need not be performed.

The first redistribution structure 130 (e.g., one or more conductive layers, etc.) may be formed along a top surface of the first dielectric layer 120. The first redistribution structure 130 (as with all redistribution structures, conductive layers, interconnection structures, and the like discussed herein) may comprise any of a variety of materials (e.g., copper, aluminum, nickel, iron, silver, gold, titanium, chromium, tungsten, palladium, combinations thereof, alloys thereof, or similar materials, etc.), but the scope of the present disclosure is not limited thereto. The first redistribution structure 130 may fill a via in the first dielectric layer 120 so as to be electrically connected to the conductive pad 110. The first redistribution structure 130 may comprise copper, for example, like the metal pad 112 of the conductive pad 110, but aspects of the present disclosure are not limited thereto. Since the first redistribution structure 130 may be vertically coupled to the conductive pad 110 and horizontally extends from the conductive pad 110, a conductive pattern may be formed regardless of the pitch or height of the conductive bump 500 coupled to the conductive pad 110. Therefore, the first redistribution structure 130 may increase a degree of freedom in designing the semiconductor device according to the present disclosure.

In addition, the electronic device coupling structure 131 for coupling the electronic device 400 to the substrate 100 may be formed using the same conductive layer or layers as the first redistribution structure 130. The electronic device coupling structure 131 may be formed in the same process as the first redistribution structure 130 and may be exposed through the first dielectric layer 120 without being connected to a separate conductive pad.

The second dielectric layer 140 may cover the first redistribution structure 130. For example, the second dielectric layer 140 may be formed to expose a region of the first redistribution structure 130 for electrical connection thereto, while covering the rest of the first redistribution structure 130. The second dielectric layer 140 may comprise any one or more of the dielectric materials discussed herein with regard to the first dielectric layer 120. The second dielectric layer 140 may, for example, comprise the same dielectric material(s) as the first dielectric layer 120 or may comprise different dielectric material(s).

The second redistribution structure 150 (e.g., one or more conductive layers, etc.) may be formed along a top surface of the second dielectric layer 140. The second redistribution structure 150 may, for example, comprise any one or more of the conductive materials discussed herein with regard to the first redistribution structure 130. The second redistribution structure 150 may, for example, comprise the same conductive material(s) as the first redistribution structure 130, or may comprise different conductive material(s). The second redistribution structure 150 may be electrically connected to the first redistribution structure 130 through a via in the second dielectric layer 140.

The third dielectric layer 160 may cover the second redistribution structure 150. For example, the third dielectric layer 160 may be formed to expose a region of the second redistribution structure 150 for electrical connection thereto, while covering the rest of the second redistribution structure 150. The third dielectric layer 160 may comprise any one or more of the dielectric materials discussed herein with regard to the first dielectric layer 120. The third dielectric layer 160 may, for example, comprise the same dielectric material(s) as the first dielectric layer 120 and/or the second dielectric layer 140, or may comprise different dielectric material(s).

The third redistribution structure 170 (e.g., one or more conductive layers, etc.) may be formed along a top surface of the third dielectric layer 160. The third redistribution structure 170 may be formed to extend along the third dielectric layer 160 up to a region that is coupled to the semiconductor die 200. The third redistribution structure 170 may, for example, comprise any one or more of the conductive materials discussed herein with regard to the first redistribution structure 130. The third redistribution structure may, for example, comprise the same conductive material(s) as the first redistribution structure 130 and/or the second redistribution structure 150, or may comprise different conductive material(s). The third redistribution structure 170 may be electrically connected to the second redistribution structure 150 through a via in the third dielectric layer 160.

The fourth dielectric layer 180 may cover the third redistribution structure 170. The fourth dielectric layer 180 may, for example, cover most of the third redistribution structure 170, except for a region of the third redistribution structure 170 to be coupled to the semiconductor die 200. The fourth dielectric layer 180 may comprise any one or more of the dielectric materials discussed herein with regard to the first dielectric layer 120. The fourth dielectric layer 180 may, for example, comprise the same dielectric material(s) as the first dielectric layer 120, second dielectric layer 140, and/or third dielectric layer 160, or may comprise different dielectric material(s).

The conductive pattern 190 (e.g., a trace, pad, land, etc.) may be electrically connected to an exposed region of the third redistribution structure 170. The conductive pattern 190 may comprise any one or more of the conductive materials discussed herein with regard to the first redistribution structure 130. The conductive pattern 190 may, for example, pass through a via in the fourth dielectric layer 180 to electrically couple to the third redistribution structure 170. The conductive pattern 190 may be exposed to be coupled to the semiconductor die 200.

The semiconductor die 200 may be electrically connected to the conductive pattern 190 of the substrate 100. The semiconductor die 200 may be electrically connected to the conductive pattern 190 of the substrate 100 by, for example, mass reflow, thermal compression, laser bonding, conductive adhesive bonding, etc., but the scope of this disclosure is not limited thereto. Though only one semiconductor die 200 is shown, there may be any number of semiconductor die (or other electronic components). In an example implementation including a plurality of semiconductor die, such implementation may comprise a plurality of semiconductor die arranged in horizontal and/or vertical directions.

Moreover, the semiconductor die 200 may comprise integrated circuit chips separated from a semiconductor wafer. In addition, the semiconductor die 200 may comprise, for example, electrical circuits, such as central processing units (CPUs), digital signal processors (DSPs), network processors, power management units, audio processors, RF circuits, wireless baseband system on chip (SoC) processors, sensors and application specific integrated circuits (ASICs).

The semiconductor die 200 may be bonded active side down to the conductive pattern 190 of the substrate 100 through micro bumps 210 or any of a variety of types of interconnection structures. The micro bumps 210 (or interconnection structures) of the semiconductor die 200 may comprise a conductive bump or ball, such as a solder bump or ball, a conductive post or pillar, such as a copper post or pillar, and/or a conductive post or pillar having a solder cap formed thereon, etc. To increase the adhesive force between the micro bump 210 of the semiconductor die 200 and the conductive pattern 190 of the substrate 100, a separate under bump metal 230 may be utilized. The under bump metal 230 may, for example, comprise one or more of chrome (Cr), nickel (Ni), palladium (Pd), gold (Au), silver (Ag), alloys thereof, and similar materials, but aspects of the present disclosure are not limited thereto.

The encapsulant 300 (or encapsulating material) may be formed on the top surface of the substrate 100 to encapsulate the semiconductor die 200. The encapsulant 300 may comprise any of a variety of encapsulating or molding materials (e.g., resin, polymer, polymer composite material, polymer with filler, epoxy resin, epoxy resin with filler, epoxy acrylate with filler, silicone resin, combinations thereof, equivalents thereof, etc.). The encapsulant 300 may, for example, help maintain the electrical interconnections between the substrate 100 and the semiconductor die 200 and protect the semiconductor die 200 by preventing impacts from being directly transferred to the semiconductor die 200.

The electronic device 400 may be coupled to the substrate 100 at a bottom side (or surface) of the substrate 100. The electronic device 400 may operate separately from the semiconductor die 200 and may include, for example, active or passive elements, like a communication module, oscillators, clocks, off-chip reactive elements such as capacitors or inductors, and/or off-chip resistors, for example.

The electronic device 400 may be electrically connected to the electronic device coupling structure 131 formed within the substrate 100. As described above, since the electronic device coupling structure 131 is exposed by the electronic device groove 120a (or cavity or aperture) formed in the first dielectric layer 120 of the substrate 100, the electronic device 400 may be connected to the electronic device coupling structure 131 such that at least a portion of the electronic device 400 is inserted into the electronic device groove 120a. Therefore, the electronic device 400 may be coupled to the substrate 100 such that at least a portion of the electronic device 400 is embedded within the substrate 100. In addition, in an example implementation, a height of the electronic device 400 does not exceed a sum of the depth of the electronic device groove 120a of the substrate 100 and a height of the conductive bump 500. In an example implementation, the height of the electronic device 400 is less than the sum of the depth of the electronic device groove 120a and the height of the conductive bump 500 (e.g., before and/or after the conductive bump 500 is reflow to attach the semiconductor device to another substrate). In an example implementation, the electronic device 400 may serve as a standoff between the electronic device and a substrate to which the electronic device is attached, for example when the conductive bump 500 is reflowed. In an example implementation, the conductive bump 500 may comprise a solid core (e.g., a copper core, etc.) to ensure that upon reflow of the conductive bump 500 to attach the semiconductor device to a substrate, there is a gap between the electronic device 400 and such substrate.

The electronic device 400 may, for example, be positioned independent of the position of the semiconductor die 200 (e.g., within or outside of the footprint of the semiconductor die 200, etc.), and at least a portion of the electronic device 400 may be embedded, or inserted, into the substrate 100, thereby reducing the overall thickness of the semiconductor device. In addition, since the height of the conductive bump 500 is minimized (e.g., relative to an implementation in which the electronic device 400 is not embedded, etc.), a fine pitch may be implemented.

The conductive bump 500 (or other interconnection structure) may be positioned under the substrate 100. The conductive bump 500 may comprise any of a variety of characteristics. For example, the conductive bump 500 (or other interconnection structure) may comprise a conductive bump or ball (e.g., a solder bump or ball, a metal or copper core solder bump or ball, etc.), a metal post or pillar (e.g., a copper post or pillar, a solder-capped metal post or pillar, etc.), etc. The conductive bump 500 may, for example, have a substantially spherical shape, as shown, although other shapes and materials are possible. The conductive bump 500 may be coupled to the bump pad 111 on the conductive pad 110 of the substrate 100. Therefore, the semiconductor device according to an embodiment of the present disclosure may input/output an electrical signal to/from the die 200 from/to an external circuit (not shown) through the conductive bump 500.

As described above, in the semiconductor device according to an embodiment of the present disclosure, the electronic device groove 120a may be formed in a region of the substrate 100 to expose the electronic device coupling structure 131 of the first redistribution structure 130 (or other redistribution structure or layer), and the electronic device 400 may be electrically connected to the electronic device coupling structure 131 where at least a portion of the electronic device 400 is inserted into the electronic device groove 120a, thereby reducing the overall thickness of the electronic device 400. In addition, since at least a portion of the electronic device 400 may be inserted into or embedded within the electronic device groove 120a, a fine pitch can be implemented by maintaining the thickness of the conductive bump 500 at a minimum level.

A method of fabrication of the semiconductor device according to an embodiment of the present disclosure is described below.

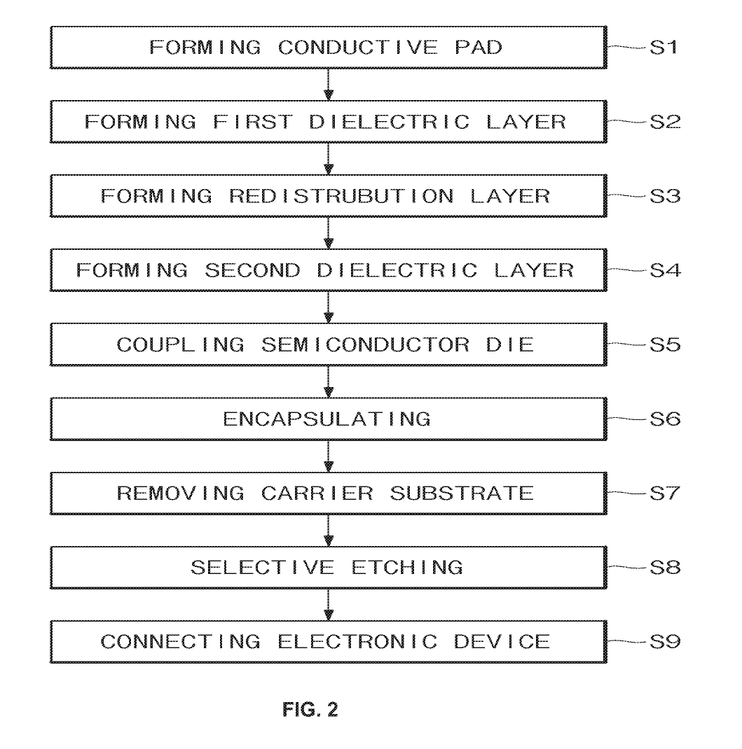

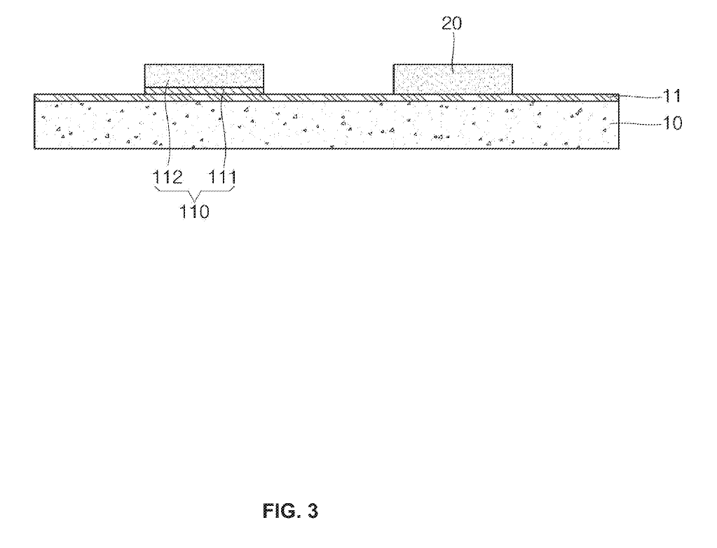

FIG. 2 is a flowchart illustrating a method of fabrication of a semiconductor device according to an embodiment of the present disclosure, and FIGS. 3 to 9 illustrate various steps of the method of fabrication of a semiconductor device shown in FIG. 2.

Referring first to FIG. 2, the method of fabrication of the semiconductor device according to an embodiment of the present disclosure may comprise forming a conductive pad (S1), forming a first dielectric layer (S2), forming a redistribution structure (S3), forming a second dielectric layer (S4), coupling a semiconductor die (S5), encapsulating (S6), removing a carrier substrate (S7), selective etching (S8), and connecting an electronic device (S9). Various steps of the method of fabrication of the semiconductor device shown in FIG. 2 are described with reference to FIGS. 3 to 9.

Referring to FIGS. 2 and 3, in forming the conductive pad (step S1), a carrier substrate 10 is provided with a silicon oxide layer 11 (or other dielectric layer) on its top surface, and a conductive pad 110 and an electronic device region pad 20 on a top surface of the silicon oxide layer 11.

The carrier substrate 10 may, for example, be cored or coreless. The carrier substrate 10 may comprise one or more layers of any of a variety of dielectric materials, for example inorganic dielectric material (e.g., Si₃N₄, SiO₂, SiON, SiN, oxides, nitrides, etc.) and/or organic dielectric material (e.g., a polymer, polyimide (PI), benzocyclobutene (BCB), polybenzoxazole (PBO), bismaleimide triazine (BT), a molding material, a phenolic resin, an epoxy, etc.), but the scope of the present disclosure is not limited thereto. The carrier substrate 10 may, for example, comprise silicon or any of a variety of semiconductor materials. The carrier substrate 10 may also, for example, comprise a glass or metal plate (or wafer). The carrier substrate 10 may be any of a variety of configurations. For example, the carrier substrate 10 may be wafer or panel form. The carrier substrate 10 may also, for example, be in diced or singulated form. The substrate may also be referred to as an interposer.

The dielectric layer 11 may, for example, comprise characteristics of any of the dielectric layers discussed herein. In an example implementation, the dielectric layer 11 may comprise a silicon oxide layer or other inorganic dielectric layer.

As described above, the conductive pad 110 may comprise a bump pad 111 and a metal pad 112. The bump pad 111 may, for example, comprise an under bump metallization structure. Step S1 may comprise forming the bump pad 111 in any of a variety of manners, non-limiting examples of which are provided herein. In an example implementation, the under bump metallization (“UBM”) structure, which may also be referred to as an under bump metal structure, may for example comprise a layer of titanium-tungsten (TiW), which may be referred to as a layer or seed layer. Such layer may, for example, be formed by sputtering. Also for example, the UBM structure may comprise a layer of copper (Cu) on the layer of TiW. Such layer may also, for example, be formed by sputtering. In another example implementation, forming a UBM structure may comprise forming a layer of titanium (Ti) or titanium-tungsten (TiW) by sputtering, (ii) forming a layer of copper (Cu) on the titanium or titanium-tungsten layer by sputtering, and (iii) forming a layer of nickel (Ni) on the copper layer by electroplating. Note however, that the UBM structure and/or processes utilized to form the UBM structure are not limited to the examples given. For example, the UBM structure may comprise a multilayered structure of chrome/chrome-copper alloy/copper (Cr/Cr-Cu/Cu), titanium-tungsten alloy/copper (Ti—W/Cu), aluminum/nickel/copper (Al/Ni/Cu), equivalents thereof, etc. The UBM structure may also, for example, comprise aluminum, palladium, gold, silver, alloys thereof, etc. Note that in various example implementations, the bump pad 111 (or UBM structure) need not be formed.

The metal pad 112 may comprise any of a variety of materials (e.g., copper, aluminum, nickel, iron, silver, gold, titanium, chromium, tungsten, palladium, combinations thereof, alloys thereof, equivalents thereof, etc.), but the scope of the present disclosure is not limited thereto. Step S1 may comprise forming the metal pad 112 in any of a variety of manners, non-limiting examples of which are provided herein. The metal pad 112 may be formed or deposited utilizing any one or more of a variety of processes (e.g., electrolytic plating, electroless plating, chemical vapor deposition (CVD), sputtering or physical vapor deposition (PVD), atomic layer deposition (ALD), plasma vapor deposition, printing, screen printing, lithography, etc.), but the scope of the present disclosure is not limited thereto. In addition, step S1 may comprise forming the electronic device region pad 20, for example in the same manner in which the metal pad 112 is formed (e.g., in a same process step. In an example implementation, in contrast to the conductive pad 110, the electronic device region pad 20 might not include the bump pad 111 (or the like), for example being formed directly on the silicon oxide instead of a UBM structure that was formed on the silicon oxide.

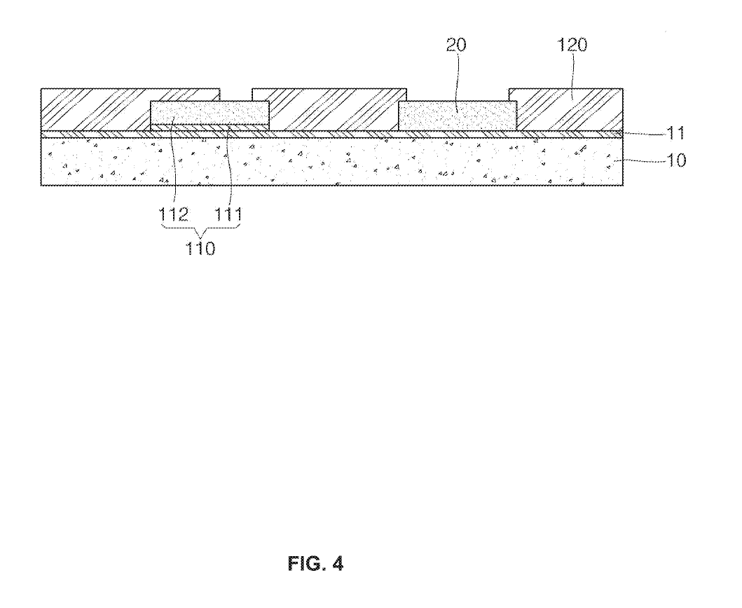

Referring to FIGS. 2 and 4, in forming the first dielectric layer (step S2), the first dielectric layer 120 may be formed on a top surface of the carrier substrate 10. The first dielectric layer 120 may, for example, be formed to cover regions of the conductive pad 110 and the electronic device region pad 20, while exposing portions of the conductive pad 110 and the electronic device region pad 20 for electrical connection thereto.

The first dielectric layer 120 may comprise one or more layers of any of a variety of dielectric materials, for example inorganic dielectric material (e.g., Si₃N₄, SiO₂, SiON, SiN, oxides, nitrides, combinations thereof, equivalents thereof, etc.) and/or organic dielectric material (e.g., a polymer, polyimide (PI), benzocyclobutene (BCB), polybenzoxazole (PBO), bismaleimide triazine (BT), a molding material, a phenolic resin, an epoxy, silicone, acrylate polymer, combinations thereof, equivalents thereof, etc.), but the scope of the present disclosure is not limited thereto.

Step S2 may comprise forming the first dielectric layer 120 in any of a variety of manners. For example, the first dielectric layer 120 may be formed using any one or more of a variety of processes (e.g., spin coating, spray coating, printing, sintering, thermal oxidation, physical vapor deposition (PVD), chemical vapor deposition (CVD), metal organic chemical vapor deposition (MOCVD), atomic layer deposition (ALD), low pressure chemical vapor deposition (LPCVD), plasma enhanced chemical vapor deposition (PECVD), plasma vapor deposition (PVD), sheet lamination, evaporating, etc.), but the scope of the present disclosure is not limited thereto.

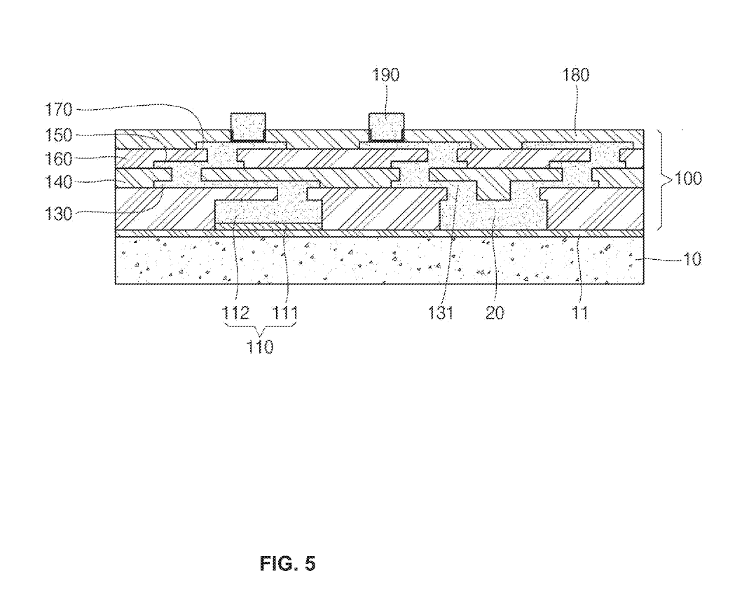

Referring to FIGS. 2 and 5, in forming the redistribution layer (step S3), a first redistribution structure 130 (e.g., one or more conductive layers, etc.) may be formed by forming a pattern made of a conductive material on a top surface of the first dielectric layer 120. The first redistribution structure 130 may be electrically connected to the exposed conductive pad 110 and the exposed electronic device region pad 20 and may extend along the top surface of the first dielectric layer 120. In addition, the electronic device coupling structure 131 may be formed on the electronic device region pad 20 thereby electrically coupling the electronic device coupling structure 131 to the electronic device region pad 20.

The first redistribution structure 130 and electronic device coupling structure 131 (as with all redistribution structures, conductive layers, interconnection structures, and the like discussed herein) may comprise any of a variety of materials (e.g., copper, aluminum, nickel, iron, silver, gold, titanium, chromium, tungsten, palladium, combinations thereof, alloys thereof, equivalents thereof, etc.), but the scope of the present disclosure is not limited thereto. Step S3 may comprise forming the first redistribution structure 130 and electronic device coupling structure 131 utilizing any one or more of a variety of processes (e.g., electrolytic plating, electroless plating, chemical vapor deposition (CVD), sputtering or physical vapor deposition (PVD), atomic layer deposition (ALD), plasma vapor deposition, printing, screen printing, lithography, etc.), but the scope of the present disclosure is not limited thereto.

Referring to FIGS. 2 and 5, in forming the second dielectric layer (step S4), a second dielectric layer 140 may be formed on the first redistribution structure 130, except for a portion of the first redistribution structure 130 that is exposed for electrical connection thereto. The second dielectric layer 140 may comprise any one or more of the dielectric materials discussed herein with regard to the first dielectric layer 120. The second dielectric layer 140 may, for example, comprise the same dielectric material(s) as the first dielectric layer 120 or may comprise different dielectric material(s). Step S4 may, for example, comprise forming second dielectric layer 140 in any of the manners discussed herein with regard to the first dielectric layer 120 (e.g., with regard to step S2, etc.).

In addition, as illustrated in FIG. 5, after forming the second dielectric layer 140, a second redistribution structure 150, a third dielectric layer 160, a third redistribution structure 170, a fourth dielectric layer 180 and a conductive pattern 190 may then be formed. The formation of the layers including the second dielectric layer 140, the second redistribution structure 150, the third dielectric layer 160, the third redistribution structure 170, the fourth dielectric layer 180, and the conductive pattern 190 may be simplified or eliminated according to the desired interconnection complexity. For example, any of such dielectric layers and/or the forming thereof may share any or all characteristics with the first and/or second dielectric layers 120 and 140 and/or the forming thereof, discussed herein. Also for example, any of such redistribution structures and/or the forming thereof may share any or all characteristics with the first redistribution layer 130 and/or the forming thereof, discussed herein.

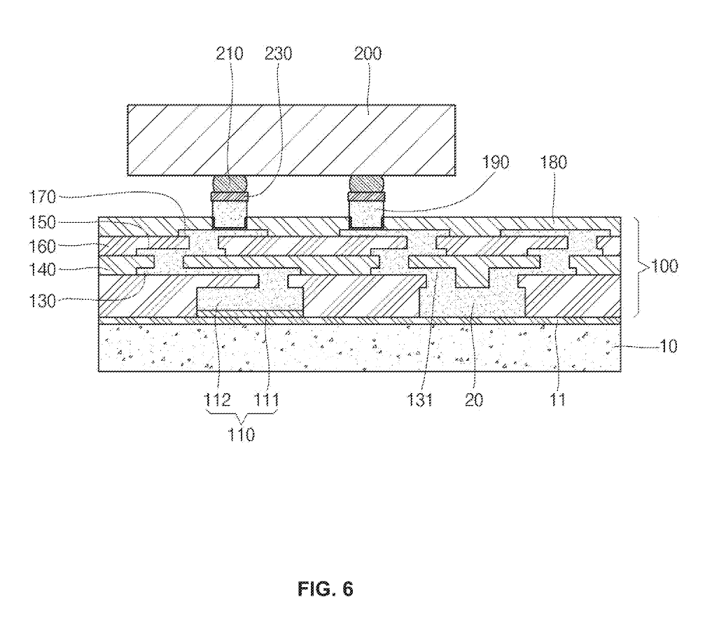

Referring to FIGS. 2 and 6, in coupling the semiconductor die (step S5), the semiconductor die 200 may be coupled to a top portion of the conductive pattern 190. Step S5 may comprise attaching (or mounting) the semiconductor die 200 to the substrate 100 (or conductive pattern 190 thereof) utilizing any of a variety of types of interconnection structures (e.g., conductive balls or bumps, solder balls or bumps, metal posts or pillars, copper posts or pillars, solder-capped posts or pillars, solder paste, conductive adhesive, etc.). Step S5 may comprise mounting the semiconductor die 200 (and/or other electronic components) to the substrate utilizing any of a variety of bonding techniques (e.g., thermocompression bonding, mass reflow, laser reflow, adhesive attachment, etc.). In an example implementation as discussed herein, the semiconductor die 200 may be bonded active side down to be coupled to the conductive pattern 190 through the micro bump 210, and the under bump metal 230 may be formed (e.g., as discussed herein) between the semiconductor die 200 and the conductive pattern 190 to increase adhesion of the die 200 to the substrate 100.

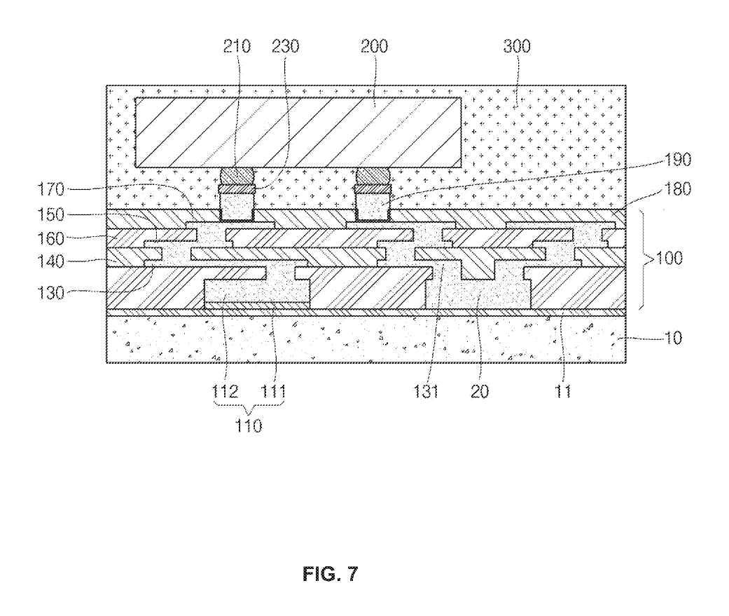

Referring to FIGS. 2 and 7, in encapsulating the package (step S6), an encapsulant 300 may be formed on the substrate 100 to encapsulate the semiconductor die 200. In addition, although not separately illustrated, the encapsulant 300 may be formed to expose a top surface of the semiconductor die 200 to its top surface for heat dissipation. In another example scenario, the encapsulant 300 may be ground down to the top surface of the semiconductor die 200.

The encapsulant 300 (or encapsulating material) may be formed on the top surface of the substrate 100 to encapsulate the semiconductor die 200. The encapsulant 300 may comprise any of a variety of encapsulating or molding materials (e.g., resin, polymer, polymer composite material, polymer with filler, epoxy resin, epoxy resin with filler, epoxy acrylate with filler, silicone resin, combinations thereof, equivalents thereof, etc.). Step S6 may comprise forming the encapsulant 300 in any of a variety of manners (e.g., compression molding, transfer molding, liquid encapsulant molding, vacuum lamination, paste printing, film assisted molding, etc.).

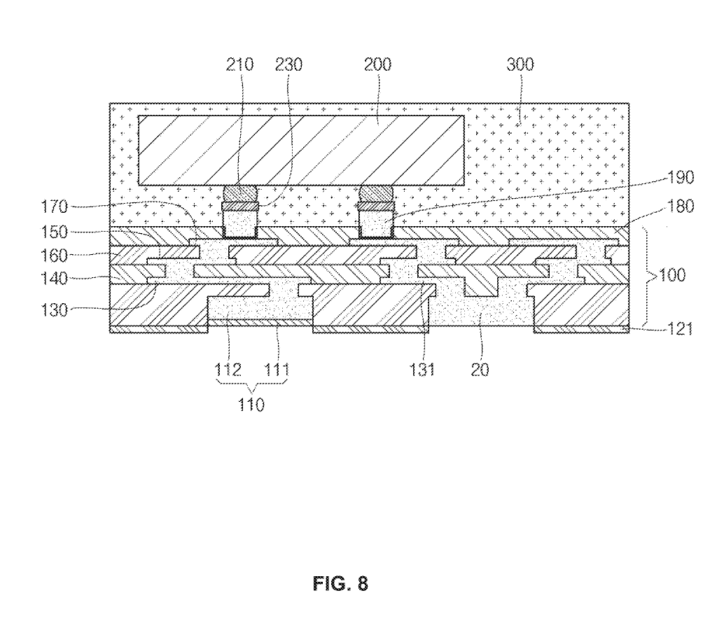

Referring to FIGS. 2 and 8, in removing the carrier substrate (S7), the carrier substrate 10 may be separated from the substrate 100 (e.g., in-whole or in-part), for example by grinding, peeling, etching, etc. When the carrier substrate 10 is removed, the dielectric layer 121 may remain. In addition, the metal pad 111 of the conductive pad 110 and the electronic device region pad 20 may be exposed by partially etching the dielectric layer 121.

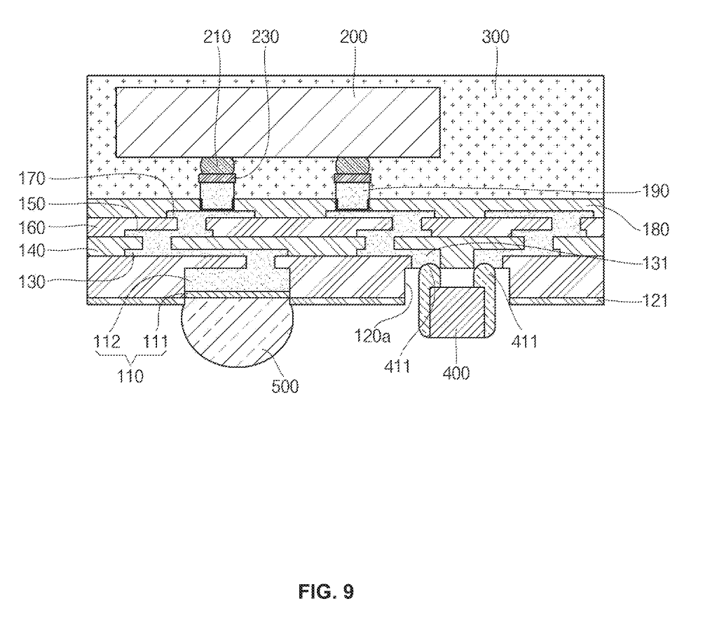

Referring to FIGS. 2 and 9, for selective etching (step S8), the electronic device region pad 20 may be selectively etched and removed from the exposed metal pad 111 and the exposed electronic device region pad 20. Step S8 may comprise forming the electronic device groove 120a (or cavity or aperture) in any of a variety of manners. For example, since the electronic device region pad 20 and the metal pad 111 comprise a different material, selective dry or wet etching may be performed using a difference between etch rates of the electronic device region pad 20 and the metal pad 111. Accordingly, the electronic device groove 120a may be formed on the substrate 100, and the electronic device coupling structure 131 of the first redistribution structure 130 may be exposed through the electronic device groove 120a. Also for example, step S8 may comprise utilizing mechanical ablation, laser ablation, plasma ablation, etc. to form the electronic device groove 120a and expose the electronic device coupling structure 131.

Referring to FIGS. 2 and 9, in connecting the electronic device (S9), at least a portion of the electronic device 400 may be inserted into the electronic device groove 120a to be electrically connected to the electronic device coupling structure 131. The connecting of the electronic device 400 may, for example, be performed utilizing any of a variety of bonding techniques (e.g., thermocompression bonding, mass reflow, laser reflow, adhesive attachment, etc.). In addition, as illustrated in FIG. 9, the conductive bump 500 (or any of a variety of interconnection structures, examples of which are provided herein) may be formed using a solder material on the metal pad 111.

The electronic device 400 may be connected to the electronic device coupling structure 131 such that at least a portion of the electronic device 400 is inserted into the electronic device groove 120a. Therefore, the electronic device 400 may be coupled to the substrate 100 such that at least a portion of the electronic device 400 is embedded within the substrate 100. In addition, in an example implementation, a height of the electronic device 400 does not exceed a sum of the depth of the electronic device groove 120a of the substrate 100 and a height of the conductive bump 500. In an example implementation, the height of the electronic device 400 is less than the sum of the depth of the electronic device groove 120a and the height of the conductive bump 500 (e.g., before and/or after the conductive bump 500 is reflow to attach the semiconductor device to another substrate). In an example implementation, the electronic device 400 may serve as a standoff between the electronic device and a substrate to which the electronic device is attached, for example when the conductive bump 500 is reflowed. In an example implementation, the conductive bump 500 may comprise a solid core (e.g., a copper core, etc.) to ensure that upon reflow of the conductive bump 500 to attach the semiconductor device to a substrate, there is a gap between the electronic device 400 and such substrate

In an example embodiment of the disclosure, a semiconductor device with etched grooves for embedded devices comprises a substrate comprising a top surface and a bottom surface, a groove extending into the substrate from the bottom surface, and a redistribution structure in the substrate between the top surface of the substrate and the bottom surface of the substrate. A semiconductor die may be coupled to the top surface of the substrate. An electronic device may be at least partially within the groove and electrically coupled to the redistribution structure. A conductive pad may be on the bottom surface of the substrate. A conductive bump may be on the conductive pad. The electronic device in the groove may extend beyond the bottom surface of the substrate a distance that is less than a height of the conductive bump from the bottom surface of the substrate. An encapsulant may encapsulate the semiconductor die and the top surface of the substrate. The electronic device may comprise a capacitor. The redistribution structure may be electrically coupled to a second redistribution structure in the substrate. The semiconductor die may be electrically coupled to the second redistribution structure.

While various aspects supporting the disclosure have been described with reference to certain example embodiments, it will be understood by those skilled in the art that various changes may be made and equivalents may be substituted without departing from the scope of the present disclosure. In addition, many modifications may be made to adapt a particular situation or material to the teachings of the present disclosure without departing from its scope. Therefore, it is intended that the present disclosure not be limited to the particular example embodiments disclosed, but that the present disclosure will include all embodiments falling within the scope of the appended claims.

What is claimed is:

1. A semiconductor device comprising:
a substrate comprising:
a top surface and a bottom surface;
a groove extending into the substrate from the bottom surface; and
a redistribution structure in the substrate between the top surface of the substrate and the bottom surface of the substrate;
a semiconductor die coupled to the top surface of the substrate; and
an electronic device at least partially within the groove and electrically coupled to the redistribution structure.

2. The semiconductor device according to claim 1, comprising a conductive pad on the bottom surface of the substrate.

3. The semiconductor device according to claim 2, comprising a conductive bump on the conductive pad.

4. The semiconductor device according to claim 3, wherein the electronic device in the groove extends beyond the bottom surface of the substrate a distance that is less than a height of the conductive bump from the bottom surface of the substrate.

5. The semiconductor device according to claim 1, comprising an encapsulant encapsulating the semiconductor die and the top surface of the substrate.

6. The semiconductor device according to claim 1, wherein the electronic device comprises a capacitor.

7. The semiconductor device according to claim 1, wherein the redistribution structure is electrically coupled to a second redistribution structure in the substrate.

8. The semiconductor device according to claim 7, wherein the semiconductor die is electrically coupled to the second redistribution structure.

9. A semiconductor device comprising:
a substrate comprising:
a top surface and a bottom surface;
a redistribution structure in the substrate between the top surface of the substrate and the bottom surface of the substrate; and
an etched region extending into the substrate from the bottom surface to the redistribution structure;
a semiconductor die coupled to the top surface of the substrate; and
an electronic device at least partially within the etched region and electrically coupled to the redistribution structure.

10. The semiconductor device according to claim 9, comprising a conductive pad on the bottom surface of the substrate.

11. The semiconductor device according to claim 10, comprising a conductive bump on the conductive pad.

12. The semiconductor device according to claim 11, wherein the electronic device in the etched region extends beyond the bottom surface of the substrate a distance that is less than a height of the conductive bump from the bottom surface of the substrate.

13. The semiconductor device according to claim 9, comprising an encapsulant encapsulating the semiconductor die and the top surface of the substrate.

14. The semiconductor device according to claim 9, wherein the electronic device comprises a capacitor.

15. The semiconductor device according to claim 9, wherein the redistribution structure is electrically coupled to a second redistribution structure in the substrate.

16. The semiconductor device according to claim 15, wherein the semiconductor die is electrically coupled to the second redistribution structure.

17. A method of fabricating a semiconductor device, the method comprising:
providing a substrate comprising:
a top surface and a bottom surface; and
a redistribution structure in the substrate between the top surface of the substrate and the bottom surface of the substrate;
etching a region of the substrate from the bottom surface to the redistribution structure;
coupling a semiconductor die to the top surface of the substrate; and
coupling an electronic device to the redistribution structure, the electronic device positioned at least partially within the etched region.

18. The method according to claim 17, comprising encapsulating the semiconductor die and the top surface of the substrate with an encapsulant.

19. The method according to claim 17, comprising forming a conductive bump on the bottom surface of the substrate.

20. The method according to claim 19, wherein the electronic device in the etched region extends beyond the bottom surface of the substrate a distance that is less than a height of the conductive bump from the bottom surface of the substrate.
